(19) United States
(12) Patent Application Publication
(10) Pub. No.: US 2016/0204368 A1
(43) Pub. Date: Jul. 14, 2016

(54) SOLAR CELL AND SOLAR CELL MODULE

(71) Applicant: Kabushiki Kaisha Toshiba, Minato-ku (JP)

(72) Inventors: Yuki KUDO, Yokohama (JP); Hideyuki NAKAO, Setagaya (JP); Satoshi TAKAYAMA, Kawasaki (JP); Akihiko ONO, Kita (JP); Haruhi OOOKA, Kawasaki (JP)

(73) Assignee: Kabushiki Kaisha Toshiba, Minato-ku (JP)

(21) Appl. No.: 15/079,290

(22) Filed: Mar. 24, 2016

Related U.S. Application Data
(63) Continuation of application No. PCT/JP2014/062398, filed on May 8, 2014.

(30) Foreign Application Priority Data
Sep. 24, 2013 (JP) 2013-196819

(51) Int. Cl. H01L 51/44; H01L 27/30

(52) U.S. Cl. CPC H01L 51/44; H01L 27/301

(57) ABSTRACT

According to one embodiment, a solar cell includes a substrate, a stacked body, and an optical layer. The substrate is light-transmissive. The stacked body is provided at the substrate. The stacked body includes a first electrode, a photoelectric conversion film, and a second electrode, the photoelectric conversion film including an organic semiconductor. The second electrode is light-transmissive. The optical layer is provided at the substrate. The optical layer includes a plurality of lenses. A focal length of each of the plurality of lenses is shorter than 0.5 times a distance between the stacked body and each of the plurality of lenses.

### CROSS-REFERENCE TO RELATED APPLICATIONS

This is a continuation application of International Application PCT/JP2014/062398, filed on May 8, 2014; the entire contents of which are incorporated herein by reference.

### FIELD

Embodiments described herein relate generally to a solar cell and solar cell module.

### BACKGROUND

There is a solar cell that includes an organic semiconductor in which a conductive polymer, fullerene, etc., are combined. There is a solar cell module that includes multiple solar cells. A photoelectric conversion film of the solar cell including the organic semiconductor can be formed by a simple method such as coating, printing, etc. It is desirable to increase the photoelectric conversion efficiency of the solar cell and the solar cell module including the organic semiconductor.

### BRIEF DESCRIPTION OF THE DRAWINGS

FIG. 1A and FIG. 1B are schematic views showing a solar cell according to a first embodiment;

FIG. 2 is a cross-sectional view schematically showing the solar cell according to the first embodiment;

FIG. 3 is a cross-sectional view schematically showing another solar cell according to the first embodiment;

FIG. 4A and FIG. 4B are schematic views showing a solar cell module according to a second embodiment;

FIG. 5 is a partial cross-sectional view schematically showing an enlarged portion of the solar cell module according to the second embodiment;

FIG. 6A and FIG. 6B are partial cross-sectional views schematically showing portions of other solar cell modules according to the second embodiment;

FIG. 7A and FIG. 7B are partial cross-sectional views schematically showing a portion of a solar cell module according to a third embodiment;

FIG. 8 is a graph showing an example of measurement results of the characteristics of the solar cell; and

FIG. 9 is a plan view schematically showing a photovoltaic power generation panel according to a fourth embodiment.

### DETAILED DESCRIPTION

According to one embodiment, a solar cell includes a substrate, a stacked body, and an optical layer. The substrate is light-transmissive. The stacked body is provided at the substrate. The stacked body includes a first electrode, a photoelectric conversion film, and a second electrode, the photoelectric conversion film including an organic semiconductor. The second electrode is light-transmissive. The optical layer is provided at the substrate. The optical layer includes a plurality of lenses. A focal length of each of the plurality of lenses is shorter than 0.5 times a distance between the stacked body and each of the plurality of lenses.

According to one embodiment, a solar cell module includes a substrate, a plurality of stacked bodies, and an optical layer. The substrate is light-transmissive. The plurality of stacked bodies are provided at the substrate. Each of the plurality of stacked bodies includes a first electrode, a photoelectric conversion film, and a second electrode, the photoelectric conversion film including an organic semiconductor. The second electrode is light-transmissive. The optical layer is provided at the substrate. The plurality of stacked bodies are electrically connected to each other. The optical layer includes a plurality of lenses. The focal length of each of the plurality of lenses is shorter than 0.5 times a distance between the stacked body and each of the plurality of lenses.

Various embodiments will be described hereinafter in detail with reference to the accompanying drawings.

The drawings are schematic or conceptual; and the relationships between the thicknesses and widths of portions, the proportions of sizes between portions, etc., are not necessarily the same as the actual values thereof. Further, the dimensions and/or the proportions may be illustrated differently between the drawings, even for identical portions.

In the drawings and the specification of the application, components similar to those described in regard to a drawing thereinabove are marked with like reference numerals, and a detailed description is omitted as appropriate.

### First Embodiment

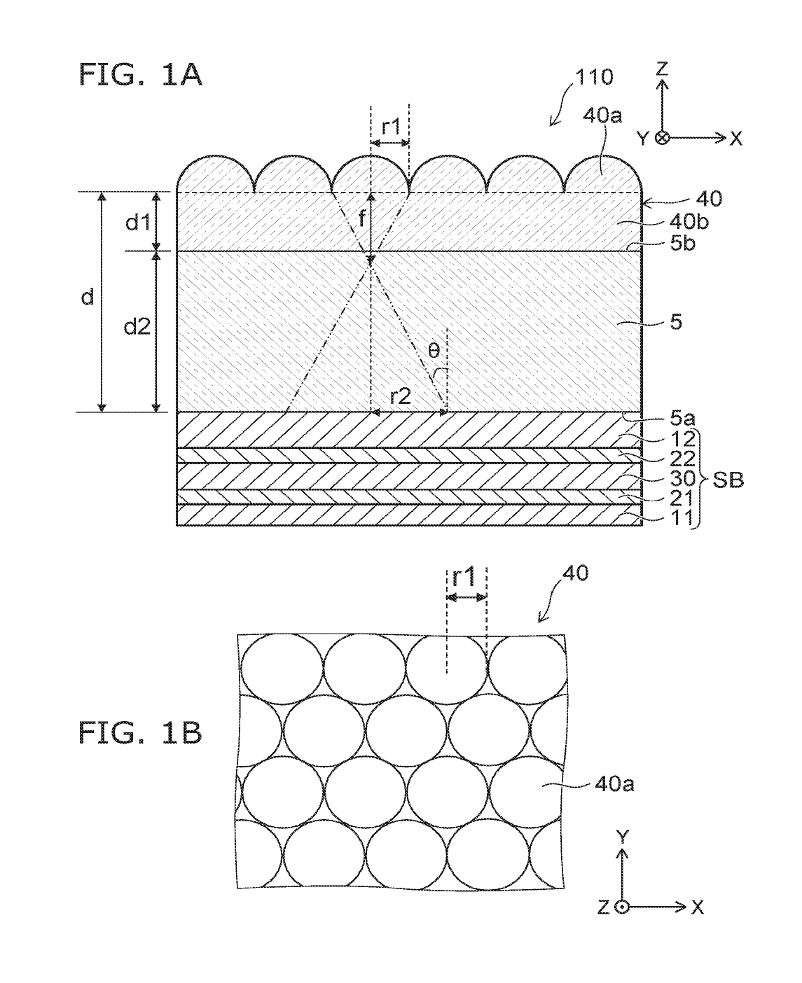

FIG. 1A and FIG. 1B are schematic views showing a solar cell according to a first embodiment.

FIG. 1A is a schematic cross-sectional view of the solar cell; and FIG. 1B is a schematic plan view showing a portion of the solar cell.

As shown in FIG. 1A, the solar cell 110 includes a substrate 5, a stacked body SB, and an optical layer 40.

The substrate 5 is light-transmissive. The substrate 5 is, for example, transparent. The substrate 5 has a first surface 5a and a second surface 5b. The second surface 5b is the surface on the side opposite to the first surface 5a. In the example, the second surface 5b is substantially parallel to the first surface 5a. The second surface 5b may be non-parallel to the first surface 5a.

Herein, a direction perpendicular to the first surface 5a is taken as a Z-axis direction. One direction perpendicular to the Z-axis direction is taken as an X-axis direction. A direction perpendicular to the Z-axis direction and the X-axis direction is taken as a Y-axis direction.

The stacked body SB is arranged with the substrate 5 in the Z-axis direction (the first direction). For example, the stacked body SB is provided to oppose the first surface 5a. For example, the stacked body SB is provided on the first surface 5a of the substrate 5.

The stacked body SB includes a first electrode 11, a second electrode 12, and a photoelectric conversion film 30. The photoelectric conversion film 30 is provided between the substrate 5 and the first electrode 11. The second electrode 12 is provided between the substrate 5 and the photoelectric conversion film 30. The second electrode 12 is light-transmissive. The second electrode 12 is, for example, transparent. The second electrode 12 is, for example, a transparent electrode.

In the example, the stacked body SB further includes a first intermediate layer 21 and a second intermediate layer 22. The first intermediate layer 21 is provided between the first electrode 11 and the photoelectric conversion film 30. The second intermediate layer 22 is provided between the photoelectric conversion film 30 and the second electrode 12. In other words, in the example, the first intermediate layer 21 is provided on the first electrode 11; the photoelectric conversion film 30 is provided on the first intermediate layer 21; the second intermediate layer 22 is provided on the photoelectric conversion film 30; and the second electrode 12 is provided on the second intermediate layer 22. In other words, the first electrode 11, the first intermediate layer 21, the photoelectric conversion film 30, the second intermediate layer 22, and the second electrode 12 are stacked in this order.

The optical layer 40 is provided to oppose the second surface 5b. The optical layer 40 is provided on the side of the substrate 5 opposite to the stacked body SB. In other words, the substrate 5 is disposed between the optical layer 40 and the stacked body SB. In other words, the substrate 5 is provided on the stacked body SB; and the optical layer 40 is provided on the substrate 5.

The optical layer 40 changes the travel direction of the light that is incident. For example, the optical layer 40 has light diffusability and diffuses the incident light. The optical layer 40 is, for example, a light diffusing member.

The optical layer 40 includes a support body 40b and multiple lenses 40a. The multiple lenses 40a are arranged in a direction perpendicular to the Z-axis direction. For example, the multiple lenses 40a are arranged along a surface parallel to the second surface 5b. The multiple lenses 40a of the optical layer 40 change the travel direction of the incident light. The optical layer 40 is, for example, a microlens array.

The support body 40b is provided between the substrate 5 and each of the multiple lenses 40a. The support body 40b is light-transmissive. The support body 40b is, for example, transparent. The support body 40b includes, for example, the same material as each of the multiple lenses 40a. For example, the support body 40b is formed as one body with the multiple lenses 40a. The material of the support body 40b may be different from the material of the multiple lenses 40a. The support body 40b is appropriately provided in the optical layer 40 as necessary and is omissible. In other words, the multiple lenses 40a of the optical layer 40 may be provided directly on the second surface 5b.

As shown in FIG. 1A and FIG. 1B, for example, the multiple lenses 40a have hemispherical configurations. In the example, the multiple lenses 40a having the hemispherical configurations are arranged in the X-axis direction and the Y-axis direction. The configurations of the multiple lenses 40a may be, for example, cylindrical configurations, etc. For example, the multiple lenses 40a having the cylindrical configurations extending in the Y-axis direction may be arranged in the X-axis direction. In other words, the optical layer 40 may be a lenticular lens sheet. The configurations of the multiple lenses 40a are not limited to hemispherical configurations or cylindrical configurations and may be any configuration that can change the travel direction of the incident light. Although the case is shown in FIG. 1A and FIG. 1B where the lenses are arranged as densely as possible, a gap may be provided between the lenses.

A focal length f of the multiple lenses 40a is shorter than 0.5 times a distance d in the Z-axis direction between the stacked body SB and the multiple lenses 40a. In other words, the focal length f satisfies the following Formula (1).

f<d/2 (1)

For example, the distance d is d1+d2, where d1 is the thickness (the length in the Z-axis direction) of the support body 40b, and d2 is the thickness of the substrate 5.

The thickness d2 of the substrate 5 is, for example, about 1 mm. Conversely, the total thickness of the thickness of the second electrode 12 and the thickness of the second intermediate layer 22 is, for example, about 200 nm and is about 10³ to 10⁴ times thinner. Therefore, the surface area of the light incident on the photoelectric conversion film 30 is substantially the same as the surface area of the light incident on the second electrode 12. Therefore, in this specification, the surface area of the light incident on the photoelectric conversion film 30 is treated as being similar to the surface area of the light incident on the second electrode 12.

For example, in the case where the multiple lenses 40a have hemispherical configurations having a radius r1, for example, the focal length f of the multiple lenses 40a can be expressed by the following Formula (2).

f=r1/(n−1) (2)

In Formula (2), n is the refractive index of the substrate 5. The refractive index has wavelength dependence. In this specification, the refractive index at the vicinity of 500 nm where the intensity of sunlight is large is used as a typical value of the refractive index. The refractive index n is, for example, not less than 1.2 and not more than 2.2.

From Formula (1) and Formula (2) recited above, the radius r1 of the lenses 40a having the hemispherical configurations that satisfies Formula (1) can be expressed by the following Formula (3).

r1<d(n−1)/2 (3)

In other words, the lenses 40a that have the radius r1 satisfying Formula (3) are provided. Thereby, the lenses 40a can satisfy Formula (1).

The solar cell 110 is a photoelectric conversion device that generates, between the first electrode 11 and the second electrode 12, a voltage and a current corresponding to the light amount of the incident light. The photoelectric conversion film 30 includes an organic semiconductor. The solar cell 110 is, for example, an organic thin film solar cell. The light that contributes to the power generation of the solar cell 110 is not limited to sunlight. For example, the solar cell 110 generates power even using light emitted from a light source such as an electric bulb, etc.

In the example, the substrate 5 and the second electrode 12 are light-transmissive. In the example, the light that is incident from the second surface 5b side passes through the substrate 5 and the second electrode 12 and is incident on the photoelectric conversion film 30. Here, the light transmissivity is, for example, the property of transmitting with a transmittance of 50% or more for light that can generate excitons by being absorbed by the photoelectric conversion film 30, e.g., light of a wavelength of 500 nm.

For example, the substrate 5, the stacked body SB, and the optical layer 40 extend in the Y-axis direction. For example, the solar cell 110 has a rectangular configuration when projected onto a plane (the X-Y plane) parallel to the first surface 5a (when viewed in the Z-axis direction). The configuration of the solar cell 110 projected onto the X-Y plane is not limited to a rectangular configuration and may be any configuration.

For example, the multiple lenses 40a of the optical layer 40 change the incident angle of the incident light. For example, the optical layer 40 causes at least a portion of the incident light to be obliquely incident on the film surface of the photoelectric conversion film 30. Thereby, for example, the effective optical path length of the photoelectric conversion film 30 can be lengthened. For example, the light absorption amount of the photoelectric conversion film 30 can be improved. The incident angle is, for example, an angle θ between the incident light and the normal of the film surface of the photoelectric conversion film 30 (e.g., the Z-axis direction).

The refractive indexes of each layer of the optical layer 40, the substrate 5, the second electrode 12, the second intermediate layer 22, the photoelectric conversion film 30, etc., are different from each other. Therefore, for example, the light that is incident on the solar cell 110 is refracted at the interface of each layer. In FIGS. 1A and 1B, such a refraction phenomenon is not shown for convenience of illustration.

However, when the relationship between the distance d and the focal length f of the lenses 40a becomes d<2f, for example, a phenomenon occurs in which the light is concentrated in a portion of the photoelectric conversion film 30.

In the solar cell using an inorganic semiconductor such as silicon or amorphous silicon, an unevenness of several tens of nm to several hundred nm is provided in the semiconductor layer itself to realize light diffusion and light confinement. Therefore, for example, in the case where an optical layer that has a lens function is combined with an inorganic semiconductor solar cell, even for conditions at which light concentration in a portion of the semiconductor layer is performed by the optical layer, further light diffusion occurs due to the unevenness of the semiconductor layer; the thickness of the semiconductor layer is thick, i.e., about 500 mm or more; and as a result, the light concentration is relaxed.

On the other hand, for the photoelectric conversion film of an organic thin film solar cell, the mobility of the carriers of the photoelectric conversion film is small compared to that of the photoelectric conversion film of the inorganic semiconductor solar cell. Therefore, in the organic thin film solar cell, it is necessary to set the thickness of the photoelectric conversion film to be thin compared to that of the inorganic semiconductor solar cell, e.g., about 50 nm to 200 nm. Accordingly, in the organic thin film solar cell, it is difficult to provide an uneven structure in the photoelectric conversion film itself to realize light diffusion.

Therefore, for the conditions at which light concentration is performed by the optical layer, the light is undesirably concentrated at a portion inside the photoelectric conversion film. Because the carrier mobility of the organic semiconductor is small, the carrier generation amount per unit surface area undesirably increases due to the light concentration; the carriers are stored; and the photocurrent that can be extracted is undesirably limited. In other words, the photoelectric conversion efficiency undesirably decreases.

Conversely, in the solar cell 110 according to the embodiment, the focal length f of each of the multiple lenses 40a is set to be shorter than 0.5 times the distance d. Thereby, in the solar cell 110, the concentration of the light in one portion of the photoelectric conversion film 30 by each of the lenses 40a can be suppressed. For example, S1<S2 may be set, where S1 is the surface area of one of the lenses 40a when projected onto the X-Y plane, and S2 is the surface area of the film surface of the stacked body SB of the incident light that passes through the one of lenses 40a and is incident on the stacked body SB (the photoelectric conversion film 30). Thereby, the effective optical path length can be lengthened without light concentration; and the photoelectric conversion efficiency can be increased. In other words, the surface area S1 of the lenses 40a is the surface area of the light incident on one lens 40a. For example, in the case of the lens 40a having the hemispherical configuration, the surface area S1 and the surface area S2 can be determined by S1=πr1² and S2=πr2².

Thus, the inventors of the application discovered that the photoelectric conversion efficiency is not increased by simply providing an optical layer including multiple lenses in an organic thin film solar cell. Also, the inventors of the application discovered that the photoelectric conversion efficiency is increased by setting the focal length f of each of the multiple lenses 40a to be shorter than 0.5 times the distance d.

For example, there are cases where the planar distribution of the light intensity incident on the photoelectric conversion film 30 is nonuniform due to fluctuation of the configurations of the lenses 40a, etc. To prevent the nonuniformity of the planar distribution of the light intensity, the light that is incident on the photoelectric conversion film 30 is irradiated on the photoelectric conversion film 30 in a state of being diffused to be as wide as possible. Thereby, the light that is incident on the photoelectric conversion film 30 is averaged; and the uniformity of the planar distribution of the light intensity can be increased.

For example, the distance d is set to be as long as possible with respect to the focal length f. For example, f<d/5 is set. Thereby, the uniformity of the planar distribution of the light intensity can be increased. Further, f<d/10 may be set. Thereby, the uniformity of the planar distribution of the light intensity can be increased further.

For example, in the case of the lenses 40a having the hemispherical configurations, the following Formula (4) is satisfied.

r1<d(n−1)/5 (4)

Thereby, the uniformity of the planar distribution of the light intensity can be increased. Further, the following Formula (5) is satisfied.

r1<d(n−1)/10 (5)

Thereby, the uniformity of the planar distribution of the light intensity can be increased further.

For example, it is favorable for the refractive index of the optical layer 40 to be substantially the same as the refractive index of the substrate 5. For example, it is favorable for the absolute value of the difference between the refractive index of the optical layer 40 and the refractive index of the substrate 5 to be 0.5 or less. Thereby, the reflections of the light at the interface between the optical layer 40 and the substrate 5 can be suppressed.

It is favorable for the distance d to be, for example, not less than 50 μm and not more than 10 mm. Thereby, for example, the weight of the solar cell 110 can be suppressed while maintaining the mechanical strength of the solar cell 110. For example, the distance d is set to be not less than 500 μm and not more than 5 mm. Thereby, the balance between the mechanical strength and weight of the solar cell 110 can be set more appropriately.

For example, in the case where the distance d is set to 1 mm and the refractive index n of the substrate 5 is set to 1.5, r1 that satisfies Formula (3) is 250 μm or less. To satisfy Formula (4), r1 is 100 μm or less. To satisfy Formula (5), r1 is 50 μm or less. Thereby, the photoelectric conversion efficiency of the solar cell 110 can be increased.

The substrate 5 supports the other components. For example, the material that is used as the substrate 5 substantially is not altered by the heat, organic solvents, etc., of the formation of the second electrode 12, etc. For example, an inorganic material such as alkali-free glass, quartz glass, or the like is used as the material of the substrate 5. The material of the substrate 5 may be, for example, a polymer film or a resin material such as polyethylene, polyethylene terephthalate (PET), polyethylene naphthalate (PEN), polyimide, polyamide, polyamide-imide, a liquid crystal polymer, a cycloolefin polymer, etc. A material that is light-transmissive is used as the substrate 5. The thickness (the length along the Z-axis direction) of the substrate 5 is not particularly limited. The thickness of the substrate 5 may be any thickness as long as the substrate 5 has enough strength to support the other components.

An antireflective layer that suppresses the reflections of the incident light may be provided between the substrate 5 and the stacked body SB, between the substrate 5 and the optical layer 40, etc. The antireflective layer may include, for example, an anti-reflection coating, an anti-reflection film, an anti-reflection sheet, etc. The material of the antireflective layer may include, for example, an inorganic material such as titanium oxide, etc. The material of the antireflective layer may be, for example, an organic material such as an acrylic resin, a polycarbonate resin, etc.

In the example, the first electrode 11 is, for example, a negative electrode. In the formation of the first electrode 11, for example, a material that is conductive is formed as a film by vacuum vapor deposition, sputtering, ion plating, plating, coating, etc. For example, a conductive metal thin film, metal oxide film, etc., may be used as the material of the first electrode 11.

In the case where a material having a high work function is included in the second electrode 12, it is favorable for a material having a low work function to be included in the first electrode 11. For example, an alkaline metal, an alkaline earth metal, etc., may be used as the material having the low work function. Specifically, at least one of Li, In, Al, Ca, Mg, Sm, Tb, Yb, Zr, Na, K, Rb, Cs, or Ba, or an alloy of these elements may be used.

The first electrode 11 may be a single layer or a stacked body in which layers including materials having different work functions are stacked. The material of the first electrode 11 may be, for example, an alloy of one or more of the materials having the low work functions and another metal material. For example, gold, silver, platinum, copper, manganese, titanium, cobalt, nickel, tungsten, tin, etc., may be used as the other metal material that is added. For example, a lithium-aluminum alloy, a lithium-magnesium alloy, a lithium-indium alloy, a magnesium-silver alloy, a magnesium-indium alloy, a magnesium-aluminum alloy, an indium-silver alloy, a calcium-aluminum alloy, etc., are examples of the alloy.

The thickness of the first electrode 11 is, for example, 10 nm to 300 nm. In the case where the film thickness is thinner than the range recited above, the resistance becomes too large; and it is difficult to conduct the charge that is generated to the external circuit. In the case where the film thickness is thick, a long period of time is necessary for the formation of the first electrode 11; therefore, the material temperature increases; and there are cases where the photoelectric conversion film 30 (the organic layer) is damaged and the performance undesirably degrades. Further, because a large amount of material is used, the time occupied by the film formation apparatus lengthens which may increase the cost.

In the example, the second electrode 12 is, for example, a positive electrode. The first electrode 11 may be used as a positive electrode; and the second electrode 12 may be used as a negative electrode. A material that is light-transmissive and conductive is used as the second electrode 12. The second electrode 12 includes, for example, a conductive metal oxide film, a semi-transparent metal thin film, etc. For example, a film (NESA, etc.) that is made using conductive glass made of indium-tin-oxide (ITO), fluorine-doped tin oxide (FTO), indium-zinc-oxide, etc., may be used as the metal oxide film. ITO is a compound including indium oxide, zinc oxide, and tin oxide. The material of the metal thin film may include, for example, gold, platinum, silver, copper, etc. ITO or FTO are particularly favorable as the material of the second electrode 12. The material of the second electrode 12 may include polyaniline, a derivative of polyaniline, polythiophene, a derivative of polythiophene, and the like which are organic conductive polymers.

In the case where ITO is used as the second electrode 12, it is favorable for the thickness of the second electrode 12 to be 30 nm to 400 nm. When set to be thinner than 30 nm, the conductivity decreases; the resistance becomes high; and this may cause the photoelectric conversion efficiency to decrease. When set to be thicker than 400 nm, the flexibility of the ITO decreases; and breaking undesirably occurs easily due to the effects of stress. It is favorable for the sheet resistance of the second electrode 12 to be as low as possible. It is favorable for the sheet resistance of the second electrode 12 to be, for example, 20 Ω/square or less.

For example, the second electrode 12 may be formed by forming the materials recited above as a film by vacuum vapor deposition, sputtering, ion plating, plating, coating, etc. The second electrode 12 may be a single layer or a stacked body in which layers including materials having different work functions are stacked.

The first intermediate layer 21 is, for example, a first charge transport layer. In the example, the first intermediate layer 21 is an electron transport layer. For example, the first intermediate layer 21 blocks holes and efficiently transports electrons. Also, for example, the first intermediate layer 21 suppresses the annihilation of the excitons generated at the interface vicinity between the photoelectric conversion film 30 and the first intermediate layer 21.

The material of the first intermediate layer 21 includes, for example, a metal oxide. For example, amorphous titanium oxide obtained by hydrolysis of titanium alkoxide by a sol-gel method, etc., may be used as the metal oxide. While the method for forming the first intermediate layer 21 is not particularly limited as long as the method can form a thin film, for example, spin coating may be used. In the case where titanium oxide is used as the material of the first intermediate layer 21, it is desirable for the first intermediate layer 21 to be formed so that the thickness of the first intermediate layer 21 is, for example, a thickness of 1 nm to 20 nm. In the case where the film thickness is thinner than the range recited above, because the hole blocking effect undesirably decreases, the excitons that are generated undesirably deactivate before dissociating into electrons and holes; and it is undesirably difficult to efficiently extract the current. In the case where the film thickness is too thick, the film resistance becomes large; and the light conversion efficiency decreases because the generated current is undesirably limited. It is desirable for the coating solution to be pre-filtered using a filter. After coating the coating solution to have a regulated film thickness, heating and drying are performed using a hotplate, etc. The heating and the drying are performed while promoting hydrolysis in air at 50° C. to 100° C. for about several minutes to 10 minutes. Metal calcium and the like are favorable inorganic materials and may be formed by vacuum vapor deposition, etc.

The second intermediate layer 22 is, for example, a second charge transport layer. In the example, the second intermediate layer 22 is a hole transport layer. For example, the second intermediate layer 22 efficiently transports holes and blocks electrons. For example, the second intermediate layer 22 suppresses the annihilation of the excitons generated at the interface vicinity of the photoelectric conversion film 30. Also, for example, the second intermediate layer 22 levels (smoothes) the unevenness of the second electrode 12 and prevents shorts of the solar cell 110. The first intermediate layer 21 may be used as the hole transport layer; and the second intermediate layer 22 may be used as the electron transport layer.

The second intermediate layer 22 includes, for example, an organic conductive polymer such as a polythiophene polymer, polyaniline, polypyrrole, etc. For example, PEDOT/PSS (poly(3,4-ethylenedioxythiophene)-poly(styrene sulfonate)) or the like is used as the polythiophene polymer. For example, Clevios PH 500 (registered trademark), Clevios PH, Clevios PV P Al 4083, and Clevios HIL 1,1 of H. C. Starck, etc., are typical products for the polythiophene polymer. A metal oxide such as molybdenum oxide, nickel oxide, tungsten oxide, or the like is a favorable material as the inorganic substance.

In the case where Clevios PH 500 is used as the material of the second intermediate layer 22, it is favorable for the thickness of the second intermediate layer 22 to be, for example, 20 nm to 100 nm. In the case where the second intermediate layer 22 is too thin, the effect of preventing shorts of the second electrode 12 decreases; and shorts undesirably occur easily. In the case where the second intermediate layer 22 is too thick, the film resistance becomes large; and the photoelectric conversion efficiency decreases because the current generated by the photoelectric conversion film 30 is undesirably limited.

The method for forming the second intermediate layer 22 is not particularly limited as long as the method can form a thin film. For example, the second intermediate layer 22 may be coated by spin coating, etc. After coating the material of the second intermediate layer 22 to have the desired thickness, heating and drying are performed using a hotplate, etc. For example, it is favorable for the heating and the drying to be performed at 140° C. to 200° C. for about several minutes to 10 minutes. It is desirable for the solution that is coated to be pre-filtered using a filter.

The refractive index of the optical layer 40 is, for example, not less than 1.2 and not more than 2.2. A material that is lightfast in the visible light region is used as the optical layer 40. For example, a polymer material such as an acrylic resin, a polycarbonate resin, a silicone resin, or the like is used. For example, an inorganic material such as alkali-free optical glass or the like is used. Considering the processability, it is favorable to use an acrylic resin for which cast molding is possible and the material cost is inexpensive. For example, the optical layer 40 is adhered to the second surface 5b of the substrate 5 by bonding. For example, a bonding agent/refractive index adjusting agent is used at the bonding surface between the substrate 5 and the optical layer 40. Specifically, various transparent potting agents, various silicone gels, various silicone sols, various glass/acrylic bonding agents (e.g., Photobond (registered trademark) made by Sunrise MSI Inc., etc.), or the like is used.

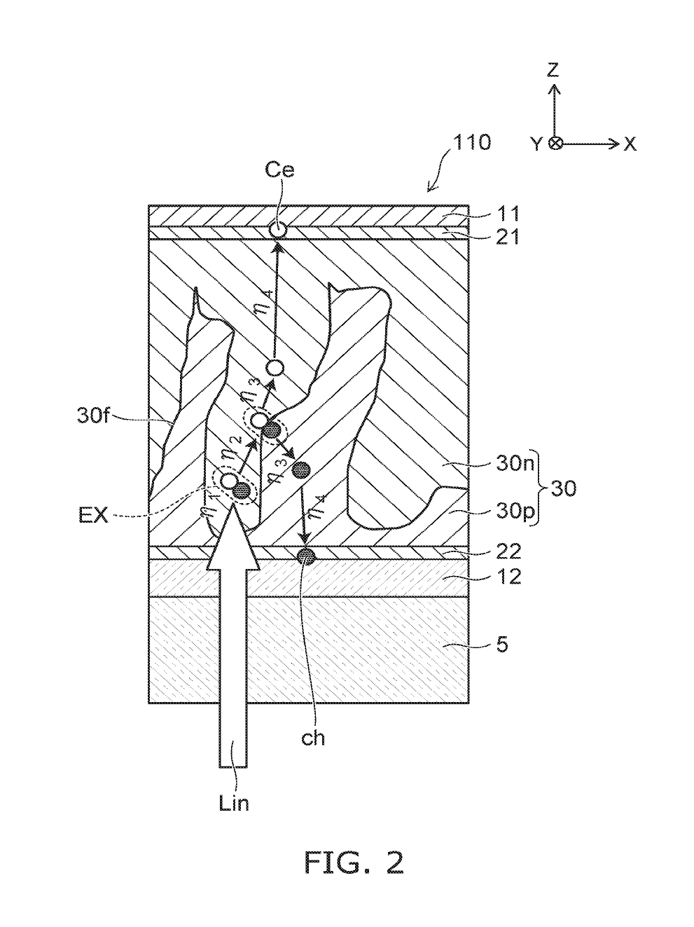

FIG. 2 is a cross-sectional view schematically showing the solar cell according to the first embodiment. As shown in FIG. 2, the photoelectric conversion film 30 includes a first semiconductor layer 30n of a first conductivity type and a second semiconductor layer 30p of a second conductivity type. For example, the second semiconductor layer 30p is provided between the second intermediate layer 22 and the first semiconductor layer 30n. In other words, for example, the second semiconductor layer 30p is provided on the second intermediate layer 22; the first semiconductor layer 30n is provided on the second semiconductor layer 30p; and the first intermediate layer 21 is provided on the first semiconductor layer 30n. For example, the first conductivity type is an n-type; and the second conductivity type is a p-type. The first conductivity type may be the p-type; and the second conductivity type may be the n-type. In the description hereinbelow, the case is described where the first conductivity type is the n-type and the second conductivity type is the p-type.

The photoelectric conversion film 30 is, for example, a thin film that has a structure in which the first semiconductor layer 30n and the second semiconductor layer 30p have a bulk heterojunction. A characteristic of the bulk heterojunction photoelectric conversion film 30 is that the first semiconductor layer 30n (the n-type semiconductor) and the second semiconductor layer 30p (the p-type semiconductor) are blended and a nano-order p-n junction spreads through the entire photoelectric conversion film 30. For example, the structure is called a microlayer-separated structure.

In the bulk heterojunction photoelectric conversion film 30, the current is obtained by utilizing the photocharge separation occurring at the junction surface between the p-type semiconductor and the n-type semiconductor which are mixed. The region that actually contributes to the power generation spreads through the entire photoelectric conversion film 30; and the p-n junction region is wider for the bulk heterojunction photoelectric conversion film 30 than for a conventional stacked organic thin film solar cell. Accordingly, compared to the stacked organic thin film solar cell, the region that contributes to the power generation is thicker for the bulk heterojunction organic thin film solar cell. Thereby, the absorption efficiency of the photons increases; and the current that is extracted increases.

The first semiconductor layer 30n includes, for example, a material having electron-accepting properties. The second semiconductor layer 30p includes, for example, a material having electron-donating properties. In the photoelectric conversion film 30 according to the embodiment, an organic semiconductor is included in at least one of the first semiconductor layer 30n or the second semiconductor layer 30p. For example, the photoelectric conversion film 30 may be a planar heterojunction film, etc.

For example, the photoelectric conversion film 30 generates excitons EX by the first semiconductor layer 30n or the second semiconductor layer 30p absorbing light Lin. The generation efficiency is η₁. The excitons EX that are generated move by diffusion toward a p-n junction surface 30f (the junction surface between the first semiconductor layer 30n and the second semiconductor layer 30p). The diffusion efficiency is η₂. Because of the life of the excitons EX, the excitons EX can move only about the diffusion length. The excitons EX that reach the p-n junction surface 30f are separated into electrons Ce and holes Ch. The efficiency of the separation of the excitons EX is η₃. The holes Ch are transported to the second electrode 12. The electrons Ce are transported to the first electrode 11. Thereby, the electrons Ce and the holes Ch (the photo carriers) are extracted to the outside. The transport efficiency of the photo carrier is η₄.

An external extraction efficiency η_{EQE} of the photo carriers generated according to the irradiated photons can be expressed by the following formula. This value corresponds to the external quantum efficiency of the solar cell 110.

η_{EQE}=η₁·η₂·η₃·η₄

The first semiconductor layer 30n includes, for example, an n-type organic semiconductor. The second semiconductor layer 30p includes, for example, a p-type organic semiconductor.

As the p-type organic semiconductor, for example, polythiophene, a derivative of polythiophene, polypyrrole, a derivative of polypyrrole, a pyrazoline derivative, an arylamine derivative, a stilbene derivative, a triphenyldiamine derivative, oligothiophene, a derivative of oligothiophene, polyvinyl carbazole, a derivative of polyvinyl carbazole, polysilane, a derivative of polysilane, a polysiloxane derivative having aromatic amine at a side chain or a main chain, polyaniline, a derivative of polyaniline, a phthalocyanine derivative, porphyrin, a derivative of porphyrin, polyphenylene vinylene, a derivative of polyphenylene vinylene, polythienylene vinylene, a derivative of polythienylene vinylene, etc., may be used. These may be used in combination. Also, a copolymer of these substances may be used. For example, a thiophene-fluorene copolymer, a phenylene ethynylene-phenylene vinylene copolymer, etc., may be used as the copolymer.

It is favorable to use polythiophene, which is a pi-conjugated conductive polymer, or a derivative of polythiophene as the p-type organic semiconductor. For polythiophene and derivatives of polythiophene, excellent stereoregularity can be ensured; and the solubility in solvents is relatively high. The polythiophene and the derivatives of polythiophene are not particularly limited as long as a compound having a thiophene skeleton is used. Specific examples of polythiophene and derivatives of polythiophene are, for example, polyalkylthiophene, polyarylthiophene, polyalkyl isothionaphthene, polyethylene dioxythiophene, etc. For example, poly(3-methylthiophene), poly(3-butylthiophene), poly(3-hexylthiophene), poly(3-octylthiophene), poly(3-decylthiophene), poly(3-dodecylthiophene), etc., may be used as the polyalkylthiophene. For example, poly(3-phenylthiophene), poly(3-(p-alkylphenylthiophene)), etc., may be used as the polyarylthiophene. For example, poly(3-butyl isothionaphthene), poly(3-hexyl isothionaphthene), poly(3-octyl isothionaphthene), poly(3-decyl isothionaphthene), etc., may be used as the polyalkyl isothionaphthene.

In recent years, derivatives of PCDTBT (poly[N-9″-hepta-decanyl-2,7-carbazole-alt-5,5-(4′,7′-di-2-thien yl-2′,1′,3′-benzothiadiazole)]) or the like which are copolymers made of carbazole, benzothiadiazole, and thiophene are known as compounds for which excellent photoelectric conversion efficiency is obtained.

These conductive polymers can be formed as a film by coating solutions of these conductive polymers dissolved in solvents. Accordingly, the advantage is provided that an organic thin film solar cell having a large surface area can be manufactured inexpensively using inexpensive equipment by printing, etc.

It is favorable to use fullerene or a derivative of fullerene as the n-type organic semiconductor. The fullerene derivative that is used here is not particularly limited as long as the fullerene derivative is a derivative having a fullerene skeleton.

Specifically, a derivative configured to have a basic skeleton of C₆₀, C₇₀, C₇₆, C₇₈, C₈₄, etc., may be used. The carbon atoms of the fullerene skeleton of the fullerene derivative may be modified with any functional group; and a ring may be formed of functional groups bonded to each other. Fullerene derivatives also include fullerene-binding polymers. For example, it is favorable for the fullerene derivative to include a functional group having high affinity with the solvent and to have high solubility in the solvent.

For example, a hydrogen atom, a hydroxide group, a halogen atom, an alkyl group, an alkenyl group, a cyano group, an alkoxy group, an aromatic heterocyclic group, etc., may be used as the functional group of the fullerene derivative. For example, a fluorine atom, a chlorine atom, etc., may be used as the halogen atom. For example, a methyl group, an ethyl group, etc., may be used as the alkyl group. For example, a vinyl group, etc., may be used as the alkenyl group. For example, a methoxy group, an ethoxy group, etc., may be used as the alkoxy group. For example, an aromatic hydrocarbon group, a thienyl group, a pyridyl group, etc., may be used as the aromatic heterocyclic group. For example, a phenyl group, a naphthyl group, etc., may be used as the aromatic hydrocarbon group.

More specifically, hydrogenated fullerene, oxide fullerene, a fullerene metal complex, etc., may be used. For example, C₆₀H₃₆, C₇₀H₃₆, etc., may be used as the hydrogenated fullerene. For example, C₆₀, C₇₀, etc., may be used as the oxide fullerene.

Among those described above, it is particularly favorable to use 60PCBM ([6,6]-phenyl C₆₁ butyric acid methyl ester) or 70PCBM ([6,6]-phenyl C₇₁ butyric acid methyl ester) as the fullerene derivative.

In the case where unmodified fullerene is used, it is favorable to use C₇₀. The generation efficiency of the photo carriers of fullerene C₇₀ is high; and fullerene C₇₀ is suited to use in the organic thin film solar cell.

In the case where the p-type semiconductor is the P3HT-type, it is favorable for the mixing ratio of the n-type organic semiconductor and the p-type organic semiconductor in the photoelectric conversion film 30 to be set to about n:p=1:1. In the case where the p-type semiconductor is the PCDTBT-type, it is favorable for the mixing ratio to be set to about n:p=4:1.

To coat the organic semiconductor, it is necessary to dissolve the organic semiconductor in a solvent. For example, an unsaturated hydrocarbon solvent, a halogenated aromatic hydrocarbon solvent, a halogenated saturated hydrocarbon solvent, an ether, etc., may be used as the solvent that is used in the coating. As the unsaturated hydrocarbon solvent, for example, toluene, xylene, tetralin, decalin, mesitylene, n-butylbenzene, sec-butylbenzene, tert-butylbenzene, etc., may be used. As the halogenated aromatic hydrocarbon solvent, for example, chlorobenzene, dichlorobenzene, trichlorobenzene, etc., may be used. As the halogenated saturated hydrocarbon solvent, for example, carbon tetrachloride, chloroform, dichloromethane, dichloroethane, chlorobutane, bromobutane, chloropentane, chlorohexane, bromohexane, chlorocyclohexane, etc., may be used. As the ether, for example, tetrahydrofuran, tetrahydropyran, etc., may be used. A halogen aromatic solvent is particularly favorable. These solvents may be used independently or mixed.

As the method for forming the solution as a film by coating, for example, spin coating, dip coating, casting, bar-coating, roll-coating, wire-bar coating, spraying, screen printing, gravure printing, flexographic printing, offset printing, gravure-offset printing, dispenser-coating, nozzle-coating, capillary-coating, inkjet, meniscus-coating, etc., may be used. These coating methods may be used independently or in combination.

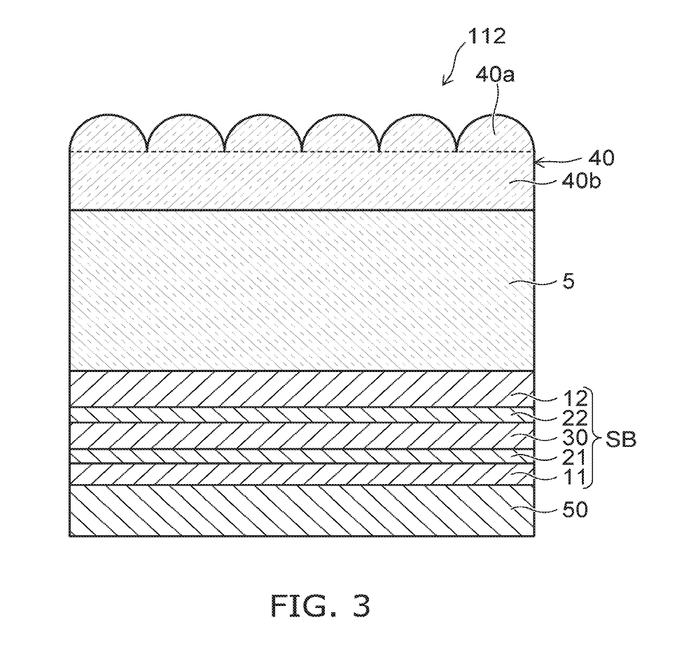

FIG. 3 is a cross-sectional view schematically showing another solar cell according to the first embodiment.

As shown in FIG. 3, the solar cell 112 further includes a sealing film 50. The sealing film 50 is provided on the side of the stacked body SB opposite to the substrate 5. In the solar cell 112, the stacked body SB is provided on the sealing film 50; the substrate 5 is provided on the stacked body SB; and the optical layer 40 is provided on the substrate 5. In other words, in the solar cell 112, the stacked body SB is disposed between the substrate 5 and the sealing film 50. For example, the sealing film 50 is adhered to the stacked body SB by a thermosetting or ultraviolet-curing epoxy resin, etc. The sealing film 50 includes, for example, an oxide film of SiOₓ, TiOₓ, etc. For example, the sealing film 50 protects the photoelectric conversion film 30, etc., from oxygen, moisture, etc. By providing the sealing film 50, for example, the durability of the solar cell 112 can be improved.

The sealing film 50 may include, for example, a metal plate or a film formed by providing a layer made of an inorganic substance or metal on the surface of a resin film. As the resin film, for example, a film made of PET, PEN, PI, EVOH, CO, EVA, PC, or PES, or a multilayer film including two or more of these films may be used. As the inorganic substance or the metal, for example, at least one of silica, titania, zirconia, silicon nitride, boron nitride, or Al may be used. For example, a desiccant, an oxygen absorber, etc., may be further included in the sealing film 50. Thereby, for example, the durability of the solar cell 112 can be improved further. Although not-shown, a gap may be provided between sealing films.

### Second Embodiment

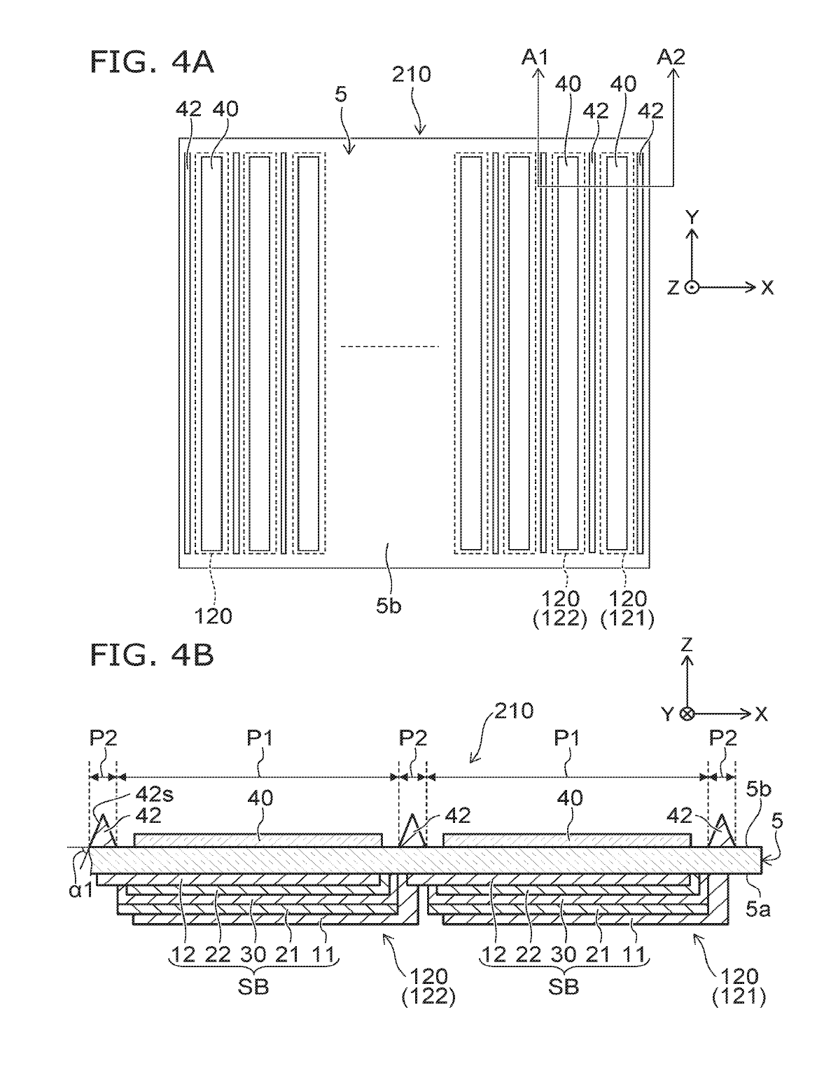

FIG. 4A and FIG. 4B are schematic views showing a solar cell module according to a second embodiment.

FIG. 4A is a plan view schematically showing the solar cell module; and FIG. 4B is a partial cross-sectional view schematically showing a portion of the solar cell module. FIG. 4B schematically shows a cross section along line A1-A2 of FIG. 4A.

As shown in FIG. 4A and FIG. 4B, the solar cell module 210 includes the substrate 5, multiple solar cells 120 (so-called cells), the optical layers 40, and reflective members 42. The substrate 5 has the first surface 5a and the second surface 5b. The configuration of the substrate 5 projected onto the X-Y plane is, for example, a rectangular configuration.

The multiple solar cells 120 are arranged on the first surface 5a. In the example, the configuration of the solar cell 120 projected onto the X-Y plane is a rectangular configuration extending in the Y-axis direction. In the example, the multiple solar cells 120 are arranged in the X-axis direction with a prescribed spacing between the multiple solar cells 120. The width in the X-axis direction (the length in the X-axis direction) of the solar cell 120 is, for example, about 10 mm to 15 mm. The length of one side of the substrate 5 is, for example, 30 cm. In this case, for example, about twenty solar cells 120 are arranged in the X-axis direction.

For example, the multiple solar cells 120 are connected in series. As described in the first embodiment recited above, a transparent electrode is used in the solar cell. The resistance value of the material included in the transparent electrode is high compared to a metal, etc. In the solar cell module 210, the multiple solar cells 120 are provided and connected in series. Thereby, for example, the increase of the resistance value of the transparent electrode as the surface area of the transparent electrode is increased can be suppressed. In the solar cell module 210, in the case where the transparent electrode is included in the solar cell 120, generally, about ten to fifteen solar cells 120 are connected in series for a substrate 5 having a size of 10 cm to 20 cm.

The configuration of the substrate 5 is not limited to a rectangular configuration and may be any configuration. The configuration and arrangement of the solar cell 120 are not limited to those recited above. For example, it is sufficient for the configuration and arrangement of the solar cell 120 to be appropriately set to match the configuration of the substrate 5, etc. For example, the number of solar cells 120 is any number corresponding to the size of the substrate 5, etc. A portion of the multiple solar cells 120 may be connected in parallel. For example, in the case where twenty solar cells 120 are included, a set of ten may be connected in series; and such sets may be connected in parallel. It is sufficient for the solar cell module 210 to include at least two solar cells 120 connected in series.

Each of the multiple solar cells 120 includes the stacked body SB. In other words, the solar cell module 210 includes multiple stacked bodies SB. The stacked body SB includes, for example, the first electrode 11, the second electrode 12, the photoelectric conversion film 30, the first intermediate layer 21, and the second intermediate layer 22. The stacked body SB is substantially the same as the stacked body SB of the solar cell 110 shown in the first embodiment recited above. The function, material, etc., of each component of the stacked body SB may be substantially the same as those of the stacked body SB described in reference to the first embodiment. Accordingly, a detailed description of such components is omitted. The multiple stacked bodies SB are arranged in a second direction perpendicular to the stacking direction of the substrate 5 and the stacked body SB. In the example, the multiple stacked bodies SB are arranged in the X-axis direction.

Here, a first solar cell 121 is one of the multiple solar cells 120. A second solar cell 122 is one other of the multiple solar cells 120. The second solar cell 122 is adjacent to the first solar cell 121. The first electrode 11 of the second solar cell 122 extends onto the second electrode 12 of the first solar cell 121. For example, the first electrode 11 of the second solar cell 122 contacts the second electrode 12 of the first solar cell 121. Thereby, the first electrode 11 of the second solar cell 122 is electrically connected to the second electrode 12 of the first solar cell 121. In other words, the second solar cell 122 is connected in series with the first solar cell 121. The electrical connection between the first solar cell 121 and the second solar cell 122 may be performed via another conductive member (connection electrode).

The substrate 5 includes multiple first portions P1 and multiple second portions P2. The multiple first portions P1 and the photoelectric conversion films 30 of the multiple solar cells 120 respectively overlap when projected onto the X-Y plane. The multiple second portions P2 and the photoelectric conversion films 30 of the multiple solar cells 120 do not overlap when projected onto the X-Y plane. In other words, each of the multiple second portions P2 is a portion overlapping the region between the multiple solar cells 120 when projected onto the X-Y plane. For example, it may be said that, when projected onto the X-Y plane, each of the first portions P1 is a portion overlapping a region contributing to the power generation; and when projected onto the X-Y plane, each of the second portions P2 is a portion overlapping a region not contributing to the power generation. When projected onto the X-Y plane, each of the second portions P2 is a portion overlapping a so-called inter-cell gap.

The optical layer 40 and the reflective member 42 are provided on the second surface 5b of the substrate 5. In the example, the solar cell module 210 includes multiple optical layers 40 and multiple reflective members 42. The multiple optical layers 40 are provided respectively on the multiple first portions P1 of the second surface 5b of the substrate 5. Each of the multiple optical layers 40 is substantially the same as the optical layer 40 of the solar cell 110 shown in the first embodiment recited above. In the example as well, the optical layer 40 includes the multiple lenses 40a. Each of the multiple lenses 40a satisfies Formula (1) recited above.

The multiple reflective members 42 are provided respectively on the multiple second portions P2 of the second surface 5b of the substrate 5. The width in the X-axis direction of each of the reflective members 42 decreases continuously in the direction from the first surface 5a toward the second surface 5b. The cross-sectional configuration in the X-Z plane of each of the reflective members 42 is a triangular configuration or a trapezoidal configuration. In the example, the cross-sectional configuration of each of the reflective members 42 is an isosceles-triangular configuration. Each of the reflective members 42 is, for example, a triangular prism configuration or a trapezoidal columnar configuration extending in the Y-axis direction.

Each of the reflective members 42 has a pair of side surfaces 42s intersecting the second surface 5b (the X-Y plane). An angle α1 between the side surface 42s and the second surface 5b is, for example, not less than 50° and not more than 85°.

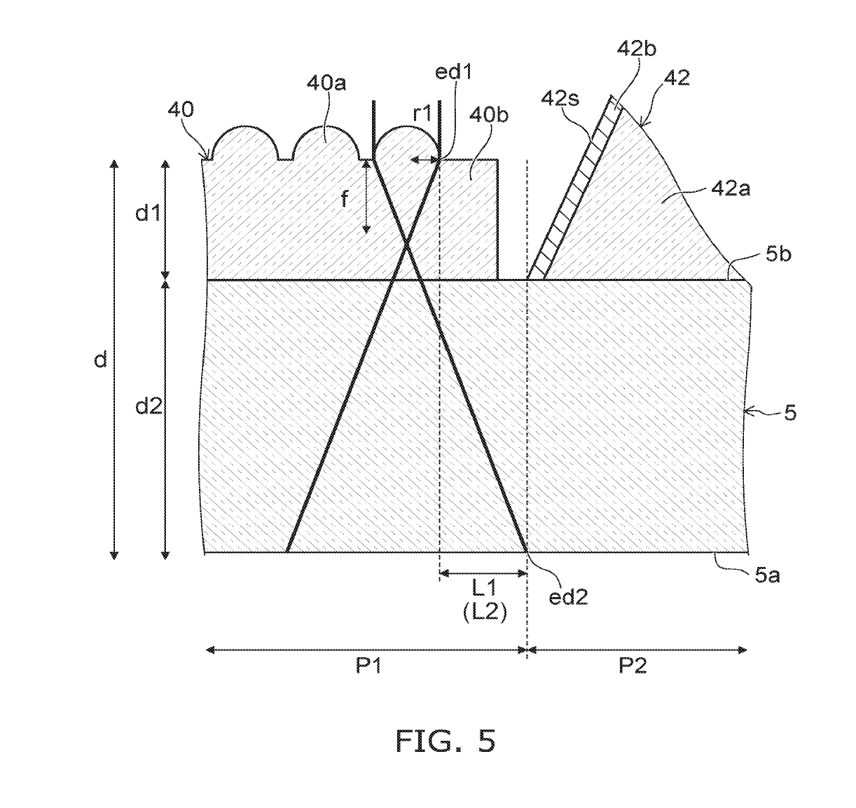

FIG. 5 is a partial cross-sectional view schematically showing an enlarged portion of the solar cell module according to the second embodiment.

As shown in FIG. 5, the reflective member 42 includes, for example, a base member 42a and a reflective film 42b. The cross-sectional configuration of the base member 42a is substantially the same as the cross-sectional configuration of the reflective member 42. For example, the reflective member 42 is formed by covering the base member 42a that is made of acrylic and has a triangular cross section with about 150 nm of Al as the reflective film 42b. Other an acrylic resin, for example, the base member 42a may include a polycarbonate resin, a silicone resin, etc. Glass, a metal, an alloy such as SUS, etc., also may be used. For example, the base member 42a may be formed as one body with the substrate 5.

It is favorable for the reflectance of the reflective film 42b to be high. Other than Al, the reflective film 42b may include, for example, various metals such as Ag, Au, Cr, etc., or a stacked structure of oxide thin films. Also, for example, Vikuiti ESR (registered trademark) which is a reflective film made by 3M Company, Luiremirror (registered trademark) of Reiko Co., Ltd., etc., may be used. Thereby, for example, the reflectance of the reflective film 42b can be set to be 80% or more.

The side surface 42s of the reflective member 42 reflects the light traveling from the second surface 5b side toward the second portion P2 and causes the light to be incident on the first portion P1. For example, the light that is traveling toward the inter-cell gap portion is guided toward the cell portion by the reflective member 42. The reflective member 42 is, for example, a light guide. Thereby, for example, the aperture ratio of the solar cell module 210 can be improved. For example, compared to the case where the reflective member 42 is not provided, an improvement of about 80% to 100% is possible.

For example, the reflective member 42 is bonded to the substrate 5 by various bonding agents. The reflective member 42 is not limited to including the base member 42a and the reflective film 42b and may be, for example, a metal having a high reflectance formed into a triangular prism configuration or a trapezoidal columnar configuration.

L1 is the distance in the X-axis direction between the second portion P2 and the lens 40a most proximal to the second portion P2. In other words, the distance L1 is the distance between the end portion in the X-axis direction (the second direction) of the lens 40a and the end portion in the X-axis direction of the reflective member 42 when the reflective member 42 and the lens 40a are projected onto the X-Y plane. In the optical layer 40 of the solar cell module 210, each of the lenses 40a is disposed to satisfy the relational expression of L1>d(n−1)−2r1. Here, as described above, d is the distance in the Z-axis direction between the stacked body SB and each of the multiple lenses 40a. n is the refractive index of the substrate 5. The refractive index n is, for example, not less than 1.2 and not more than 2.2. r1 is the radius of the lenses 40a having the hemispherical configurations.

The light that is incident on the optical layer 40 is diffused by the lenses 40a. The focal length f of the lenses 40a having the hemispherical configurations can be expressed by the approximation formula of f=r/(n−1). A distance L2 in the X-axis direction between an end portion ed1 and an end portion ed2 can be expressed by L2=d(n−1)−2r1, where the end portion ed1 is the end portion of the lens 40a having the hemispherical configuration in a direction parallel to the X-Y plane, and the end portion ed2 is the end portion in the direction parallel to the X-Y plane on the first surface 5a of the substrate 5 (the stacked body SB) of the light diffused by the lens 40a onto the first surface 5a.

For example, in the case where the distance L1 is shorter than the distance L2, the light that is diffused by the lenses 40a is undesirably incident on the second portion P2. In other words, a portion of the incident light is undesirably incident on the inter-cell gap portions of the solar cell 120. The light that is incident on the inter-cell gap portion does not contribute to the power generation. Therefore, in the case where L1<L2, the utilization efficiency of the light undesirably decreases. For example, the effect of the optical layer 40 increasing the photoelectric conversion efficiency undesirably decreases.

Conversely, in the solar cell module 210 according to the embodiment, the distance L1 is set to be not less than the distance L2. Thereby, even in the case where the optical layer 40 is provided, the light that is incident on the inter-cell gap portion can be suppressed; and the light can be effectively utilized. Accordingly, the photoelectric conversion efficiency of the solar cell module 210 can be increased.

In the example, the distance L1 is substantially the same as the distance L2. It is favorable for the distance L1 to be substantially the same as the distance L2. It is favorable for the distance L1 to be, for example, L1<10L2. Thereby, for example, the light can be caused to be incident appropriately up to the end portion of the photoelectric conversion film 30. For example, the uniformity of the planar distribution of the light intensity of the light incident on the photoelectric conversion film 30 can be increased.

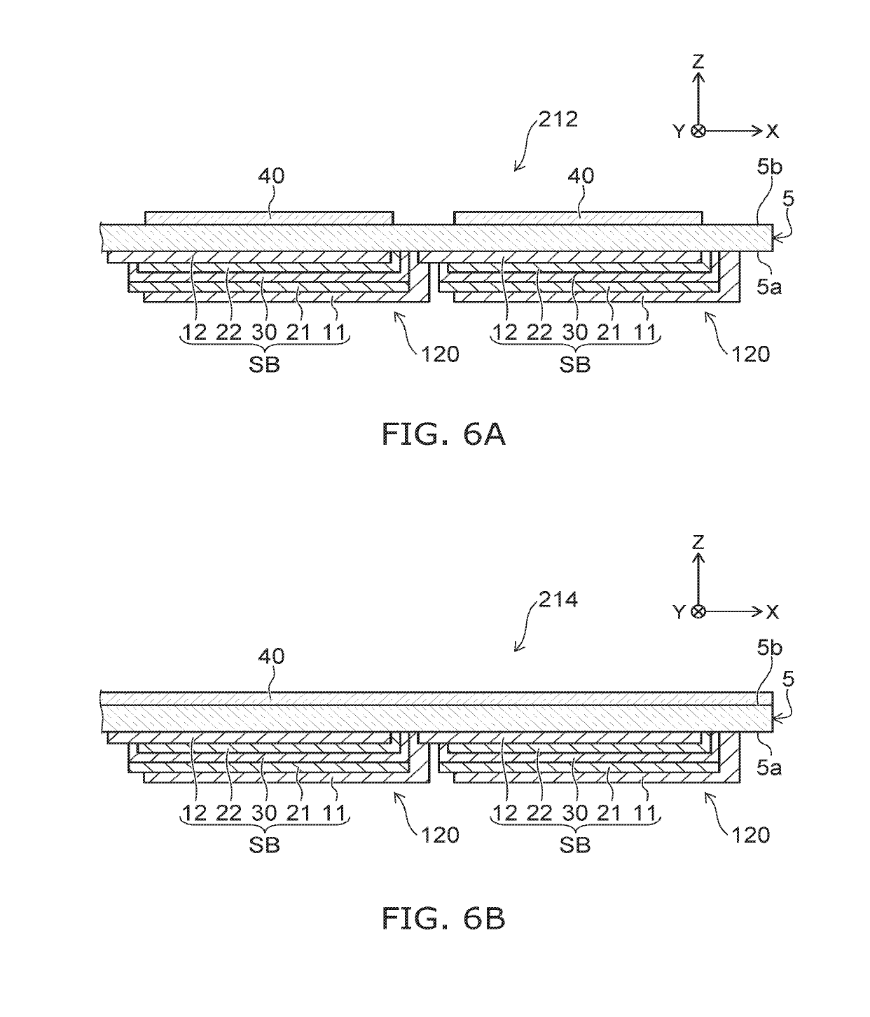

FIG. 6A and FIG. 6B are partial cross-sectional views schematically showing portions of other solar cell modules according to the second embodiment.

As shown in FIG. 6A and FIG. 6B, the reflective member 42 is omitted from the solar cell modules 212 and 214. Thus, the reflective member 42 may be omitted; and only the optical layer 40 may be provided. In such a case as well, each of the lenses 40a is provided to satisfy Formula (1) recited above. Thereby, for the solar cell modules 212 and 214 as well, the photoelectric conversion efficiency can be increased.

In the case where the reflective member 42 is omitted, for example, as in the solar cell module 212, the multiple optical layers 40 may be provided respectively on the multiple first portions P1 of the second surface 5b of the substrate 5; or as in the solar cell module 214, one optical layer 40 that opposes each of the multiple first portions P1 may be provided on the second surface 5b.

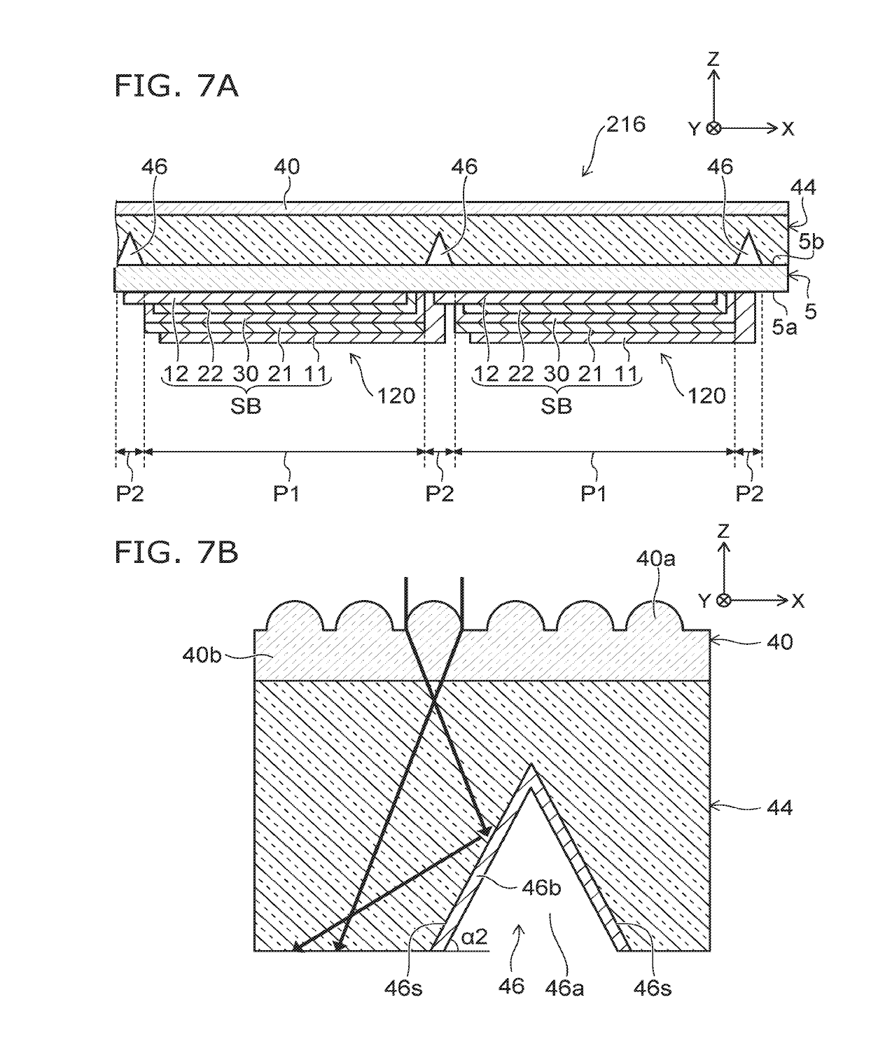

FIG. 7A and FIG. 7B are partial cross-sectional views schematically showing a portion of a solar cell module according to a third embodiment.

As shown in FIG. 7A, the solar cell module 216 includes the substrate 5, the multiple solar cells 120, the optical layer 40, and a reflective member 44. The reflective member 44 is provided between the substrate 5 and the optical layer 40. The optical layer 40 is stacked on the reflective member 44. In the example as well, each of the lenses 40a satisfies Formula (1) recited above. In other words, the focal length of the lenses 40a is less than 0.5 times the distance d between the stacked body SB and the lenses 40a. The reflective member 44 includes multiple reflectors 46. The multiple reflectors 46 are provided at the inter-cell gaps, i.e., the positions of the multiple second portions P2 of the substrate 5.

As shown in FIG. 7B, for example, each of the reflectors 46 has a concave configuration including a trench 46a. The width in the X-axis direction of each of the reflectors 46 decreases continuously in the direction from the first surface 5a toward the second surface 5b. The cross-sectional configuration in the X-Z plane of each of the reflectors 46 is, for example, a triangular configuration or a trapezoidal configuration. In the example, the cross-sectional configuration of each of the reflectors 46 is an isosceles-triangular configuration. The trench 46a has a pair of side surfaces 46s intersecting the first surface 5a. An angle α2 between the side surface 46s and the X-Y plane is, for example, not less than 50° and not more than 85°. For example, each of the reflectors 46 extends in the Y-axis direction.

Each of the reflectors 46 includes a reflective film 46b. The reflective film 46b is provided on the pair of side surfaces 46s. In other words, the reflective film 46b covers the pair of side surfaces 46s. The reflective film 46b includes a light-reflective material. The reflective film 46b may include, for example, a material having a high reflectance such as Al, etc. Other than Al, the reflective film 46b may include various metals such as Ag, Au, etc., a stacked film of oxides, Vikuiti ESR which is a reflective film made by 3M Company, Luiremirror of Reiko Co., Ltd., etc. Thus, the reflector 46 is covered with the light-reflective material.

In the case where the optical layer 40 and the reflector 46 not including the reflective film 46b are provided, a portion of the light diffused by the lenses 40a undesirably does not satisfy the conditions for total internal reflection at the interface of the side surface 46s. Therefore, in the case where the reflective film 46b is not provided in the reflector 46, a portion of the light passes through the reflector 46 and is undesirably incident on the inter-cell gap portion. Therefore, the utilization efficiency of the light decreases; and the photoelectric conversion efficiency undesirably decreases.

Conversely, in the solar cell module 216, the reflective film 46b is provided in the reflector 46. Thereby, even the light that does not satisfy the conditions for total internal reflection is reflected by the reflective film 46b and guided toward the cell portion of the solar cell 120. Accordingly, in the solar cell module 216, the utilization efficiency of the light can be increased; and the photoelectric conversion efficiency can be increased. Also, in the solar cell module 216, the aperture ratio can be improved. For example, the aperture ratio can be set to be about 80% to 100%.

Although the reflective film 46b is provided in the reflector 46 in the example, this is not limited thereto; for example, a light-reflective material filled into the trench 46a may be used as the reflector 46. In other words, the reflector 46 may not include the portion of the gap.

### First Example

In the solar cell 110, alkali-free glass (in which the thickness d2=0.7 mm and the refractive index is about 1.5) is used as the substrate 5. An ITO transparent electrode of 150 nm is formed as the second electrode 12 by sputtering. A hole transport layer having a film thickness of about 50 nm is formed as the second intermediate layer 22 by spin coating (with a rotation speed of 5000 rpm for 30 seconds) PEDOT:PSS (model number AI 4083) and by annealing in air at 140° C. for 10 minutes. Then, the sample is moved into a glovebox purged with N₂ gas; and the photoelectric conversion film 30 having a film thickness of about 75 nm is formed on the PEDOT:PSS by spin coating (with a rotation speed of 2000 rpm for 60 seconds) a solution in which PCDTBT as the p-type semiconductor and PC[70]BM as the n-type semiconductor are dissolved in dichlorobenzene and by annealing at 70° C. for 10 minutes. The ratio of the PCDTBT and the PC[70]BM is 1:4. Then, the sample is extracted from the glovebox; and an electron transport layer of TiOₓ having a film thickness of about 5 nm is formed as the first intermediate layer 21 by spin coating (with a rotation speed of 5000 rpm for 30 seconds) a precursor of Ti oxide in air and by annealing in air at 70° C. for 10 minutes. Then, the first electrode 11 is formed by vapor-depositing about 100 nm of Al by vacuum vapor deposition. Then, the solar cell 110 is formed by sealing the portion of the stacked structure described above with a sealing glass in a N₂ atmosphere. The sealing glass is not shown in FIGS. 1A and 1B.

The optical layer 40 is formed by closely adhering, with a refractive index matching agent interposed, a microlens array sheet having hemispherical configurations (d1 equal to about 100 μm) on a glass substrate which is the substrate 5 of the solar cell 110. The radius of the hemispherical lens is about 15 μm which satisfies the condition of being smaller than d(n−1)/10=40 μm of Formula (5).

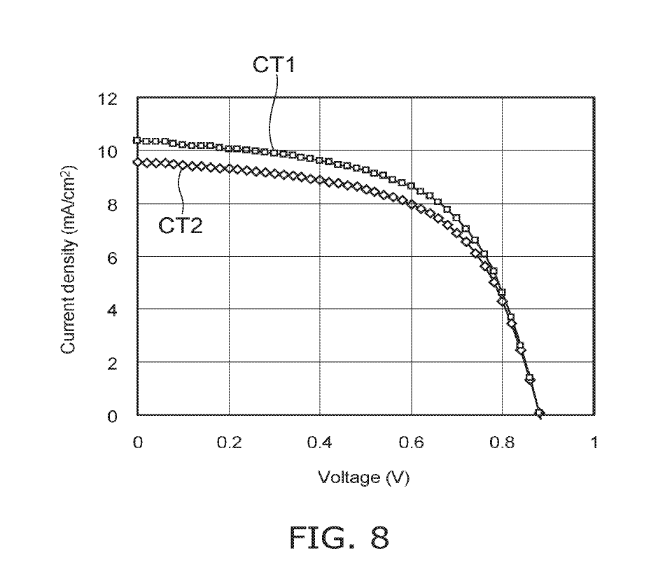

FIG. 8 is a graph showing an example of measurement results of the characteristics of the solar cell.

FIG. 8 shows an example of measurement results of the solar cell characteristics in the case where artificial sunlight corresponding to AM 1.5 is irradiated. In FIG. 8, a characteristic CT1 is an example of measurement results of the characteristic in the case where the optical layer 40 is provided. A characteristic CT2 is an example of measurement results of the characteristic in the case where the optical layer 40 is not provided.

As shown in FIG. 8, the photocurrent is increased by providing the optical layer 40. In the case where there is no optical layer 40, the short circuit current density is 9.6 mA/cm²; and the conversion efficiency is 4.9%. Conversely, in the case where the optical layer 40 is provided, the short circuit current density is 10.4 mA/cm²; the conversion efficiency is 5.3%; and an improvement of about 1.08 times is possible.

The structure that is applicable to each of the lenses 40a of the optical layer 40 is not only the convex structure having the hemispherical configuration but also a concave structure having a hemispherical configuration, a convex structure or a concave structure having a cylindrical configuration, etc. Each configuration is determined so that light concentration does not occur inside the photoelectric conversion film 30. Thereby, the photoelectric conversion efficiency can be increased.

### Comparative Example

An optical layer that includes multiple hemispherical lenses having a radius 350 μm is closely adhered, with a refractive index matching agent interposed, to a solar cell similar to that of the first example. Here, the thickness of the support body of the optical layer is about 0.3 mm. In the case with the optical layer and in the case without the optical layer as shown in Table 1, the conversion efficiency for the case with the optical layer is 4.4%; and the conversion efficiency is lower compared to 5% in the case without the optical layer. It is considered that the conversion efficiency decreases because the relationship between the thicknesses of the optical layer and/or the substrate and the focal length of the hemispherical lens does not satisfy 2f<d, and light concentration undesirably occurs inside the photoelectric conversion film.

TABLE 1

| | CONVERSION EFFICIENCY |
|---|---|
| OPTICAL LAYER | (%) |
| WITHOUT | 5.0 |
| WITH | 4.4 |

### Second Example

An example of the solar cell module 210 will now be described.

While the stacked body SB of the solar cell 120 and the optical layer 40 used in the example are similar to those of the first example, the formation method is different. Namely, in the second example, the various intermediate layers 21 and 22 and the photoelectric conversion film 30 are formed by meniscus-coating in which ink is supplied to the gap between the substrate 5 and an applicator, and coating is performed in a rectangular configuration by moving the substrate 5 or the applicator.

The reflective member 42 that has a triangular cross section is provided on each of the multiple second portions P2 of the second surface 5b of the substrate 5. The reflective member 42 is formed by providing a metal film such as Al, etc., on a base member such as acrylic or polycarbonate. Thereby, the light that is incident from the second surface 5b side is guided toward the cell portion; and the substantial aperture ratio improves. Here, the width of the cell portion (the width of the first portion P1) is 14 mm; and the width of the inter-cell gap region (the width of the second region P2) is 1 mm.

The optical layer 40 is provided on each of the multiple first portions P1 of the second surface 5b of the substrate 5. The multiple lenses 40a having the hemispherical configurations are provided in the optical layer 40. As described above, each of the lenses 40a is disposed so that L1 satisfies the relational expression of L1>d(n−1)−2r1, where L1 is the distance in the X-axis direction between the second portion P2 and the lens 40a most proximal to the second portion P2. Thereby, the diffuse light that is undesirably incident on the inter-cell gap portion can be suppressed. Here, d(n−1)−2r1=0.37 mm; and the optical layer 40 is provided so that the end portions of the lenses 40a are disposed at positions so that the length of Li is 0.37 mm or more.

Table 2 shows the short circuit current density and the conversion efficiency in the case where the length of L1 is 0 and in the case where the length of L1 is 0.4 mm. It can be seen from Table 2 that the short circuit current density and the conversion efficiency can be increased by setting the length of L1 to 0.4 mm.

TABLE 2

| LENGTH L | PHOTOCURRENT | CONVERSION EFFICIENCY |
|---|---|---|
| (mm) | (mA/cm²) | (%) |
| 0 | 9.9 | 5.0 |
| 0.4 | 10.4 | 5.3 |

### Third Example

An example of the solar cell module 216 will now be described.

The stacked body SB of a solar cell similar to that of the first example is made by meniscus-coating. In the solar cell module 216, the reflector 46 that has a triangular configuration is provided above the inter-cell gap portion. The reflector 46 is formed by providing the trench 46a having the triangular configuration in the substrate 5 such as acrylic or polycarbonate and by covering the side surface 46s of the trench 46a with an Al thin film. Here, the thickness of the reflective film 46b is 5 mm; the length of the bottom side of the trench 46a is 1 mm; and the height is 0.6 mm. The optical layer 40 is provided on the second surface 5b of the substrate 5. The light that is incident on the reflector 46 from the second surface 5b side is reflected by the reflective film 46b and guided toward the cell portion. Thereby, the substantial aperture ratio improves. Here, similarly to the second example, the width of the cell portion is 14 mm; and the width of the inter-cell gap region is 1 mm.

As in the short circuit current density and the conversion efficiency in the case with the reflective film 46b of Al in the reflector 46 and the case without the reflective film 46b of Al in the reflector 46 shown in Table 3, the short circuit current density and the conversion efficiency can be increased by providing the reflective film 46b.

TABLE 3

| REFLECTIVE | PHOTOCURRENT | CONVERSION EFFICIENCY |
|---|---|---|
| FILM | (mA/cm²) | (%) |
| WITHOUT | 10.0 | 5.1 |
| WITH | 10.3 | 5.3 |

### Fourth Embodiment

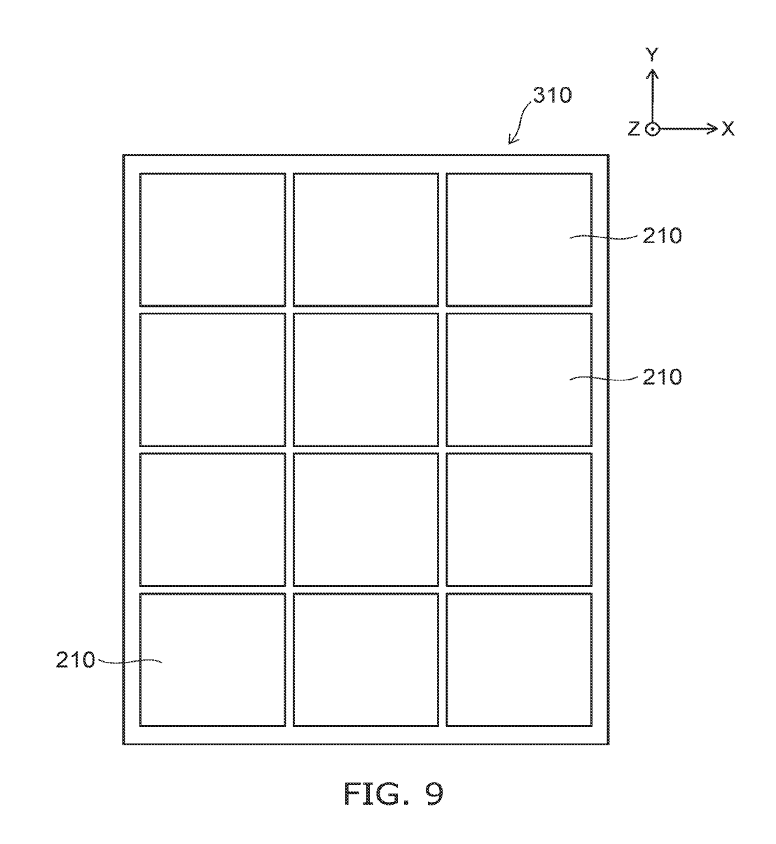

FIG. 9 is a plan view schematically showing a photovoltaic power generation panel according to a fourth embodiment.

As shown in FIG. 9, the photovoltaic power generation panel 310 includes the multiple solar cell modules 210. In the example, the photovoltaic power generation panel 310 includes twelve solar cell modules 210 arranged three in the X-axis direction and four in the Y-axis direction. The length of one side of the solar cell module 210 is about 30 cm. The size of the photovoltaic power generation panel 310 is, for example, about 1 m by 1.2 m. The multiple solar cell modules 210 are connected in series or in parallel. Thereby, the photovoltaic power generation panel 310 outputs a prescribed voltage and current. Thus, the solar cell module 210 may be used as the photovoltaic power generation panel 310 in which the multiple solar cell modules 210 are electrically connected. The number and arrangement of the solar cell modules 210 included in the photovoltaic power generation panel 310 may be set arbitrarily.

According to the embodiments, a solar cell and a solar cell module having a high photoelectric conversion efficiency are provided.

In this specification, “perpendicular” and “parallel” include not only strictly perpendicular and strictly parallel but also, for example, the fluctuation due to manufacturing processes, etc.; and it is sufficient to be substantially perpendicular and substantially parallel. In this specification, the state of being “provided on” includes not only the state of being provided in direct contact but also the state in which another component is inserted therebetween. The state of being “stacked” includes not only the state of overlapping in contact with each other but also the state of overlapping with another component inserted therebetween. The state of being “opposed” includes not only the state of directly facing each other but also the state of facing each other with another component inserted therebetween.

Hereinabove, exemplary embodiments of the invention are described with reference to specific examples.

However, the invention is not limited to these specific examples. For example, one skilled in the art may similarly practice the invention by appropriately selecting specific configurations of components included in the solar cells and solar cell modules such as the substrate, the stacked body, the first electrode, the second electrode, optical layer, lens, reflective member and the reflector, etc., from known art; and such practice is within the scope of the invention to the extent that similar effects are obtained.

Further, any two or more components of the specific examples may be combined within the extent of technical feasibility and are included in the scope of the invention to the extent that the purport of the invention is included.

Moreover, all solar cells and solar cell modules practicable by an appropriate design modification by one skilled in the art based on the solar cells and the solar cell modules described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A solar cell, comprising:
a substrate being light-transmissive;
a stacked body provided at the substrate, the stacked body including a first electrode, a photoelectric conversion film, and a second electrode, the photoelectric conversion film including an organic semiconductor, the second electrode being light-transmissive; and
an optical layer provided at the substrate,
the optical layer including a plurality of lenses,
a focal length of each of the plurality of lenses being shorter than 0.5 times a distance between the stacked body and each of the plurality of lenses.

2. The cell according to claim 1, wherein
the plurality of lenses have hemispherical configurations, and
a radius r1 satisfies the relationship of r1<d(n−1)/2, where
r1 is a radius of each of the plurality of lenses,
d is a distance between the stacked body and each of the plurality of lenses, and
n is a refractive index of the substrate.

3. The cell according to claim 1, wherein the focal length of the plurality of lenses is shorter than 0.2 times the distance between the stacked body and each of the plurality of lenses.

4. The cell according to claim 1, wherein the focal length of the plurality of lenses is shorter than 0.1 times the distance between the stacked body and each of the plurality of lenses.

5. The cell according to claim 1, wherein
the substrate has a first surface, and a second surface on a side opposite to the first surface,
the stacked body is provided on the first surface, and
the optical layer is provided on the second surface.

6. The cell according to claim 1, wherein
the stacked body further includes a first intermediate layer and a second intermediate layer,
the first intermediate layer is provided between the first electrode and the photoelectric conversion film, and
the second intermediate layer is provided between the photoelectric conversion film and the second electrode.

7. The cell according to claim 1, wherein
the optical layer further includes a support body, and
the support body is light-transmissive and is provided between the substrate and each of the plurality of lenses.

8. The cell according to claim 1, wherein
the photoelectric conversion film includes a first semiconductor layer and a second semiconductor layer,
the first semiconductor layer is of a first conductivity type, and
the second semiconductor layer is provided between the first semiconductor layer and the second electrode, is of a second conductivity type different from the first conductivity type, and has a bulk heterojunction with the first semiconductor layer.

9. The cell according to claim 1, further comprising a sealing film,
the stacked body being provided between the substrate and the sealing film.

10. A solar cell module, comprising:
a substrate being light-transmissive;
a plurality of stacked bodies provided at the substrate, each of the plurality of stacked bodies including a first electrode, a photoelectric conversion film, and a second electrode, the photoelectric conversion film including an organic semiconductor, the second electrode being light-transmissive; and
an optical layer provided at the substrate,
the plurality of stacked bodies being electrically connected to each other,
the optical layer including a plurality of lenses,
a focal length of each of the plurality of lenses being shorter than 0.5 times a distance between the stacked body and each of the plurality of lenses.

11. The module according to claim 10, wherein
the substrate has a first surface, and a second surface on a side opposite to the first surface,
the plurality of stacked bodies are provided and arranged on the first surface, and
the optical layer is provided on the second surface.

12. The module according to claim 11, wherein
a plurality of the optical layers are provided, and
the plurality of optical layers respectively oppose the photoelectric conversion films of the plurality of stacked bodies.

13. The module according to claim 11, wherein the optical layer opposes the photoelectric conversion film of each of the plurality of stacked bodies.

14. The module according to claim 11, further comprising a plurality of reflective members,
a plurality of the optical layers being provided,
the plurality of lenses having hemispherical configurations,
the plurality of stacked bodies being arranged in a second direction, a first direction being a stacking direction of the substrate and each of the plurality of stacked bodies, the second direction being a direction perpendicular to the first direction,
the plurality of optical layers satisfying the relational expression of L1>d(n−1)−2r1, where
when each of the plurality of reflective members and each of the plurality of lenses are projected onto a plane perpendicular to the first direction, L1 is a distance between an end portion in the second direction of one lens of the plurality of lenses and an end portion in the second direction of one reflective member of the plurality of reflective members most proximal to the one lens,
r1 is a radius of the one lens,
d is a distance in the first direction between the one lens and the stacked body, and
n is a refractive index of the substrate.

15. The module according to claim 14, wherein
the substrate includes:
a plurality of first portions, the photoelectric conversion films of the plurality of stacked bodies and the plurality of first portions respectively overlapping when projected onto the plane; and
a plurality of second portions, the photoelectric conversion films of the plurality of stacked bodies and the plurality of second portions not overlapping when projected onto the plane,
the plurality of optical layers are provided respectively on the plurality of first portions in the second surface, and
the plurality of reflective members are provided respectively on the plurality of second portions in the second surface.

16. The module according to claim 15, wherein a width in the second direction of each of the plurality of reflective members decreases continuously in a direction from the first surface toward the second surface.

17. The module according to claim 16, wherein
each of the plurality of reflective members has a pair of side surfaces intersecting the second surface, and
an angle between the second surface and one of the pair of side surfaces is not less than 50° and not more than 85°.

18. The module according to claim 14, wherein a distance L1 is longer than a distance L2, where L2 is a distance in the second direction between the end portion in the second direction of the one lens and an end portion on the first surface of light diffused onto the first surface by the one lens.

19. The module according to claim 11, further comprising a reflective member provided between the substrate and the optical layer,
the reflective member including a plurality of reflectors including trenches,
each of the plurality of reflectors being covered with a light-reflective material.

20. The module according to claim 19, wherein
the substrate includes:
a plurality of first portions, the photoelectric conversion films of the plurality of stacked bodies and the plurality of first portions respectively overlapping when projected onto a plane perpendicular to a stacking direction of each of the plurality of stacked bodies; and
a plurality of second portions, the photoelectric conversion films of the plurality of stacked bodies and the plurality of second portions not overlapping when projected onto the plane, and
the plurality of reflectors are provided respectively at positions overlapping the plurality of second portions when projected onto the plane.
